(19) United States
(12) Patent Application Publication
(10) Pub. No.: US 2026/0087215 A1
(43) Pub. Date: Mar. 26, 2026

(54) MACHINE LEARNING (ML)-BASED STAGE-LOOKAHEAD STATIC TIMING ANALYSIS (STA) AND GRADIENT-DESCENT DRIVEN PLACEMENT TIMING OPTIMIZATION

(71) Applicant: QUALCOMM INCORPORATED, San Diego, CA (US)

(72) Inventors: Akshay Sanjay SARODE, Pune (IN); Romain LEPERT, Amsterdam (NL); Rishubh KHURANA, Bengaluru (IN); Payal AGARWAL, Bengaluru (IN); Kartik KRISHNA KUMAR, Bangalore (IN); Mysore SRIRAM, Bengaluru (IN)

(21) Appl. No.: 18/892,140

(22) Filed: Sep. 20, 2024

(51) Int. Cl. G06F 30/327; G06F 30/337; G06N 3/047

(52) U.S. Cl. CPC G06F 30/327; G06F 30/337; G06N 3/047

(57) ABSTRACT

A machine-learning (ML)-based system may be used in the placement phase of integrated circuit chip design. The ML-based system may include a placer and a ML-based static timing analyzer. The placer may receive a floorplan and a netlist as inputs. The placer may iteratively generate and evaluate intermediate placements based on the floorplan, the netlist, and iterative feedback that is based on the intermediate placements. The ML-based static timing analyzer may provide total negative slack (TNS) gradient information based on the intermediate placements. The iterative feedback used by the placer may include this TNS gradient information. On the last iteration, the placer may output the last intermediate placement.

### DESCRIPTION OF THE RELATED ART

Electronic design automation (EDA) relates to the use of software tools for designing electronic systems, such as integrated circuit chips. An EDA workflow may begin with a logic synthesis phase, in which logic circuitry expressed in a hardware description language is transformed into a netlist. A netlist is a standardized way of describing electronic circuitry components and their interconnecting nodes. A netlist may be provided in the form of a file. Following logic synthesis, another phase of EDA workflow may relate to developing a floorplan. A floorplan describes the tentative locations or placement of blocks of related components, input/output (I/O) ports, macros, etc., on a physical chip.

A floorplan may be provided (e.g., by an engineer) as an input to a place-and-route (PnR) software tool. Based on the floorplan and a netlist file, the PnR tool may output a placement. A “placement” refers to a result (e.g., a file) that incorporates the locations of standard cells into the floorplan. The PnR tool may include a static timing analysis (STA) engine that determines performance results such as endpoint arrival times and a metric of overall timing performance known as total negative slack (TNS). The PnR tool may include a cost function that evaluates performance results received from the STA engine. The gradient of the cost function with respect to placement may be used as feedback to the placement function of the PnR tool, and the PnR tool may iteratively refine the placement based on this feedback before settling on a placement to provide as an output.

The placement that the PnR tool outputs may be analyzed (e.g., by an engineer) to determine whether it meets desired characteristics, commonly referred to as power, performance and area or “PPA.” If the placement does not meet PPA requirements or is otherwise deemed unsatisfactory, the floorplan may be modified and the modified floorplan provided to the PnR tool. Based on the modified floorplan, the PnR tool may output another placement. Such floorplan modification and placement may continue in an iterative manner until a floorplan that yields a satisfactory “initial placement” is developed.

Following the initial placement, the PnR tool may further be used to perform a placement with netlist optimization, thereby refining the initial placement. Netlist optimization may include buffer insertion, netlist restructuring, cell upsizing/downsizing, cell voltage switching, etc. Following the further placement with netlist optimization, further STA may be performed on the placed, post-optimization netlist. Note that the netlist optimization and the placement both are timing-aware, and involve internal (i.e., within the PnR tool) feedback from the STA engine.

The foregoing steps of placement (initially unoptimized and then with netlist optimizations) followed by STA may be performed iteratively until a satisfactory placement is developed. This iterative workflow may take a substantial amount of time, such as several days for a large chip design. Not only may the high computational load of the netlist optimizations slow the placement process, but the output of the PnR tool on each iteration may include a substantial amount of information that may not be needed until after the final iteration and is therefore often discarded until the final iteration. The use of such a feature-rich PnR tool (i.e., placement with netlist optimization, iteratively performed) may hamper the ability to quickly explore or evaluate the placements resulting from a number of different floorplans.

### SUMMARY OF THE DISCLOSURE

Systems, methods, computer-readable media, and other examples are disclosed for providing a placement in designing an integrated circuit chip.

An exemplary method for providing a placement may include receiving, by a placer, a floorplan and a netlist. The placer may be configured to iteratively generate and evaluate intermediate placements based on the floorplan, the netlist, and iterative feedback, which may be based on the intermediate placements. The method may further include providing, by a machine learning (ML)-based static timing analyzer, total negative slack (TNS) gradient information based on the intermediate placements. The iterative feedback may include this TNS gradient information. The method may still further include providing, by the placer, an output placement comprising a last iteration of the intermediate placements.

An exemplary computer-readable medium for providing a placement may have computer-executable code stored therein, which may include a placer and a ML-based static timing analyzer. The placer may be configured to receive a floorplan and a netlist and to iteratively generate and evaluate intermediate placements based on the floorplan, the netlist, and iterative feedback, which may be based on the intermediate placements. The ML-based static timing analyzer may be configured to provide TNS gradient information based on the intermediate placements. The iterative feedback may include this TNS gradient information. The placer may be further configured to provide an output placement comprising a last iteration of the intermediate placements.

An exemplary system for providing a placement may include a user interface and a processing system. The processing system may include one or more memories and one or more processors and may be configured to include a placer and a ML-based static timing analyzer. The placer may be configured to receive a floorplan and a netlist and to iteratively generate and evaluate intermediate placements based on the floorplan, the netlist, and iterative feedback, which may be based on the intermediate placements. The ML-based static timing analyzer may be configured to provide TNS gradient information based on the intermediate placements. The iterative feedback may include this TNS gradient information. The placer may be further configured to provide an output placement comprising a last iteration of the intermediate placements.

### BRIEF DESCRIPTION OF THE DRAWINGS

In the Figures, like reference numerals refer to like parts throughout the various views unless otherwise indicated. For reference numerals with letter character designations such as “102A” or “102B”, the letter character designations may differentiate two like parts or elements present in the same Figure. Letter character designations for reference numerals may be omitted when it is intended that a reference numeral to encompass all parts having the same reference numeral in all Figures.

FIG. 1 is a block diagram of a computing system configured for performing placement in designing an integrated circuit chip, in accordance with exemplary embodiments.

FIG. 2 is a block diagram illustrating a system having a machine-learning (ML)-based fast post-netlist optimization static timing analyzer, in accordance with exemplary embodiments.

FIG. 3 illustrates an exemplary netlist portion having a post-optimization configuration, in accordance with exemplary embodiments.

FIG. 4 illustrates an exemplary netlist portion having an unoptimized configuration, in accordance with exemplary embodiments.

FIG. 5 is a block diagram illustrating an example of the ML-based fast post-netlist optimization static timing analyzer, in accordance with exemplary embodiments.

FIG. 6 illustrates a set of path-based stage-lookahead model features, in accordance with exemplary embodiments.

FIG. 7 is a flow diagram illustrating a method for providing training samples for the path-based stage-lookahead delay model, in accordance with exemplary embodiments.

FIG. 8 illustrates another exemplary netlist portion having a post-optimization configuration, in accordance with exemplary embodiments.

FIG. 9 illustrates another exemplary netlist portion having an unoptimized configuration, in accordance with exemplary embodiments.

FIG. 10 is a block diagram illustrating another example of the ML-based fast post-netlist optimization static timing analyzer, in accordance with exemplary embodiments.

FIG. 11 is a block diagram illustrating a stage-lookahead graph-based analysis (GBA)-mimicking DAGNN model, in accordance with exemplary embodiments.

FIG. 12 illustrates an example of driver and receiver nodes in the GBA-mimicking DAGNN model, in accordance with exemplary embodiments.

FIG. 13 is a flow diagram illustrating a method for providing training samples for the GBA-mimicking DAGNN model, in accordance with exemplary embodiments.

FIG. 14 illustrates still another exemplary netlist portion having an unoptimized configuration, in accordance with exemplary embodiments.

FIG. 15 illustrates still another exemplary netlist portion having a post-optimization configuration, in accordance with exemplary embodiments.

FIG. 16 is a block diagram illustrating a computing system configured for generating training sample sets.

FIG. 17 is a flow diagram illustrating a method of operation of the system of FIG. 1.

FIG. 18 illustrates a set of DAGNN model features, in accordance with exemplary embodiments.

### DETAILED DESCRIPTION

The word “exemplary” is used herein to mean “serving as an example, instance, or illustration.” The word “illustrative” may be used herein synonymously with “exemplary.” Any aspect described herein as “exemplary” is not necessarily to be construed as preferred or advantageous over other aspects.

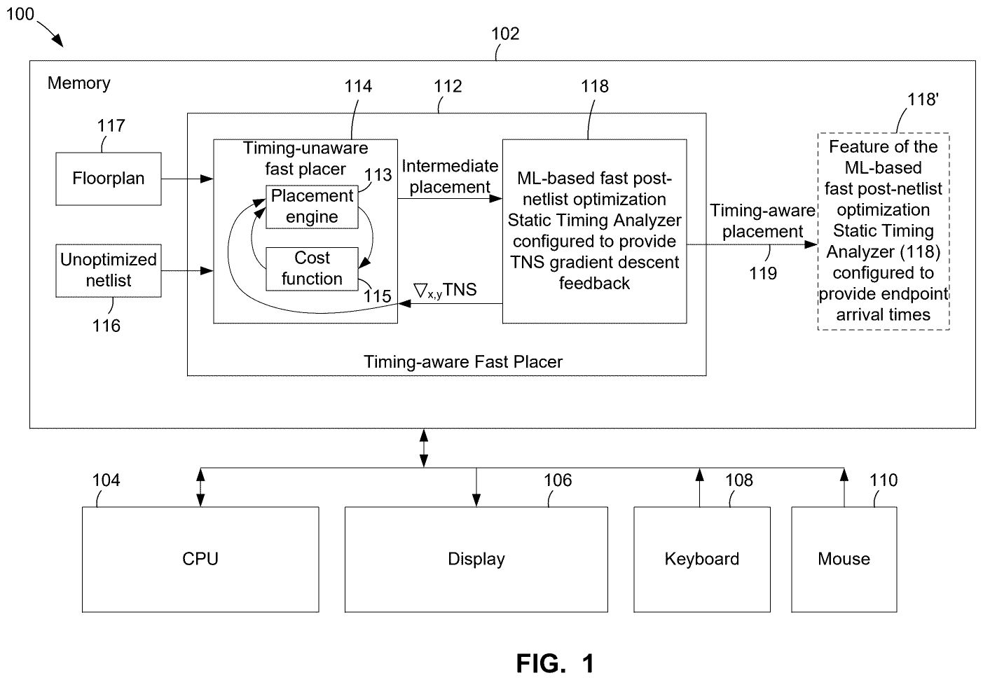

As shown in FIG. 1, in an illustrative or exemplary embodiment a computing system 100 may be used in designing integrated circuit chips (not shown). The computing system 100 may include, for example, a memory 102, a central processing unit (CPU) 104, a display 106, a keyboard 108, and a mouse 110. Although not shown for purposes of clarity, the computing system 100 may include further components, such as, for example, non-volatile memory, removable or portable memory devices, network interfaces, ports, etc. The memory 102 may comprise, for example, dynamic random access memory (DRAM) and may serve as a main memory through which the CPU 104 executes software, performs operations upon data, etc. The memory 102 and CPU 104 may together provide a processing system configured through the execution of software to perform the operations and methods described herein. Such software may include electronic design automation (EDA) software components. The EDA software components may include a timing-aware fast placer 112 to which solutions described herein may relate. Although not shown for purposes of clarity, EDA software components known in the art may also be included. For example, while the timing-aware fast placer 112 relates to the phase of chip design known as placement, other EDA software components may be included that relate to other phases of chip design.

Using the keyboard 108, mouse 110, display 104, etc., as a user interface or portion of a user interface, a user may interact with and operate the computing system 100, as configured with the above-described EDA software components, to perform integrated circuit chip placement and other operations. It should be understood that the timing-aware fast placer 112 and related data are conceptually shown in FIG. 1 for purposes of clarity as stored in or residing in the memory 102. Nevertheless, one of ordinary skill in the art will appreciate that such software components, data, etc., may be retrieved from non-volatile storage or via a network and executed by the CPU 104 in portions (e.g., instructions, retrieved on an as-needed basis) in accordance with conventional computing principles. Execution of such EDA software components and other software as may be described herein may control aspects of any of the methods described herein or configure aspects any of the systems described herein. The memory 102 and any other such memory or other non-transitory storage medium having software or firmware stored therein in computer-readable form for execution by a CPU or other processor hardware may be an example of a “computer-readable medium,” as the term is understood in the patent lexicon.

The timing-aware fast placer 112 may include a timing-unaware fast placer 114. The timing-unaware fast placer 114 may initially receive as an input an unoptimized netlist 116 and a floorplan 117. Based on the unoptimized netlist 116, the floorplan 117, and iterative feedback, the timing-unaware fast placer 114 may iteratively generate intermediate placements. The iterative feedback may be based in part on the intermediate placements. For example, the timing-unaware fast placer 114 may include a placement engine 113 and a cost function 115. On each iteration, the placement engine 113 may generate or provide an intermediate placement. The gradient of the cost function 115 with respect to the placement informs the next intermediate placement. The iterations may continue until a threshold criterion is met (which could be different from the cost function). The placement engine 113 may use that value as feedback to generate or provide the next intermediate placement. The timing-unaware fast placer 114 may be characterized as “fast” because it may operate faster than placers that use timing information (from static timing analysis) in performing the placement operations (i.e., are timing-aware) and that perform explicit netlist optimization. Performing placement operations without regard to timing information and without explicit netlist optimization may reduce processing load and, accordingly, processing time.

The timing-aware fast placer 112 may also include a machine learning (ML)-based fast post-netlist-optimization static timing analyzer 118. The ML-based fast post-netlist-optimization static timing analyzer 118 may be configured to receive the aforementioned intermediate placement as an input. The ML-based fast post-netlist-optimization static timing analyzer 118 may be configured to provide total negative slack (TNS) gradient information based on each intermediate placement received from the timing-unaware fast placer 114. This TNS gradient information may be included as another portion of the above-described feedback used by the timing-aware fast placer 114. In other words, the timing-aware fast placer 114 may generate or provide successive intermediate placements based on not only the feedback provided by the gradient of the cost function 115 but also on the feedback (i.e., TNS gradient information) provided by the ML-based fast post-netlist-optimization static timing analyzer 118.

After a number of iterations by the timing-unaware fast placer 114, the value provided by the cost function 115 may indicate that the last intermediate placement (i.e., the result of the last iteration) meets the above-referenced threshold criteria. In accordance with gradient-descent principles, the TNS gradient information helps minimize TNS, while the gradient of the cost function 115 drives successive intermediate placements toward lower values of the cost function 115. The timing-aware fast placer 112 may then provide this last intermediate placement or timing-aware placement 119 as an output.

The timing-aware fast placer 112 may be characterized as “fast” because its constituent timing-unaware fast placer 114 and ML-based fast post-netlist-optimization static timing analyzer 118, coupled together and operating together in the manner described herein, may have a combined effect on the placement operations that may enable faster completion of the floorplanning and placement phases of the chip design workflow than could be achieved with traditional feature-rich placers that perform explicit netlist optimization (not shown). For example, using the timing-aware fast placer 112, a user (e.g., an engineer) may be able to quickly generate and compare or otherwise evaluate different floorplans 117 (by evaluating the placements based thereon), a sub-phase of floorplanning and placement that may be referred to as floorplan exploration.

The ML-based fast post-netlist optimization static timing analyzer 118 may include a feature 118′ configured to provide ML-predicted endpoint arrival times (e.g., in the form of a file) based on the timing-aware placement 119. These endpoint arrival times may aid a user in determining whether to accept the timing-aware placement 119 for use in the chip design or to begin again using a different floorplan 117 (i.e., the aforementioned floorplan exploration). The ML-predicted endpoint arrival times may be provided more rapidly than if the “true” arrival times were determined using static timing analysis (STA) on placement results provided by a traditional feature-rich STA tool that provides timing using library table lookup. The ML-predicted endpoint arrival times and endpoint arrival times obtained using conventional STA on placement results provided by a traditional PnR tool may differ by only a small amount of error, while the timing-aware fast placer 112 may provide the aforementioned benefit of faster overall floorplanning and placement completion.

It should be noted that neither the timing-unaware fast placer 114 nor the ML-based fast post-netlist-optimization static timing analyzer 118 actually (or “explicitly”) performs netlist optimization. Rather, the ML-based fast post-netlist-optimization static timing analyzer 118 predicts post-netlist-optimization delays using a pre-trained ML model, described below. The absence of explicit netlist optimization may speed the floorplanning exploration phase of the chip design workflow. Conventionally, netlist optimization and determining delays using STA is a phase or stage of the chip design workflow that is performed after the placement or floorplanning stage. The solutions described herein, which use ML-based prediction, predict post-netlist-optimization timing directly from the unoptimized netlist, and hence may be referred to as “stage-lookahead.”

The timing-unaware fast placer 114 may be provided in any manner. For example, the timing-unaware fast placer 114 may be obtained in the form of open-source software from public online repositories as known to one of ordinary skill in the art. The ML-based fast post-netlist optimization static timing analyzer 118 may be provided in the manner described below.

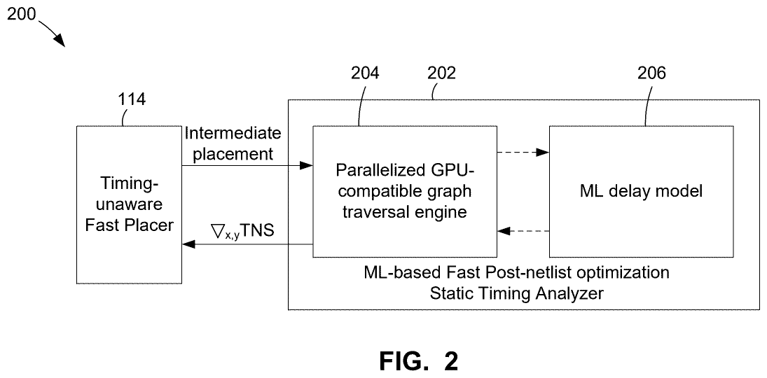

In FIG. 2, a system 200 may include a ML-based fast post-netlist optimization static timing analyzer 202. The ML-based fast post-netlist optimization static timing analyzer 202 may be an example of the above-described ML-based fast post-netlist optimization static timing analyzer 118 (FIG. 1). Accordingly, the ML-based fast post-netlist optimization static timing analyzer 202 may be coupled to the timing-unaware fast placer 114 as described above with regard to FIG. 1.

The ML-based fast post-netlist optimization static timing analyzer 202 may include a graph traversal engine 204 and a ML delay model 206. The graph traversal engine 204 may be parallelized and graphics processing unit (GPU)-compatible. As a netlist may be represented by a graph, where the graph vertices or nodes represent netlist startpoints, cells (in a cell-based graph, or pins in a pin-based graph), and endpoints, and where the graph edges represent interconnections between netlist nodes, the graph traversal engine 204 may be configured to traverse a netlist. The graph traversal engine 204 may be configured to compute the worst (i.e., slowest) delay from all possible startpoints in the netlist to each endpoint in the netlist using the ML delay model 206 as a delay predictor. The term “delay predictor,” as understood by one of ordinary skill in the art, refers to a ML regression model trained on delay data as labels. The following examples may aid understanding of these operations.

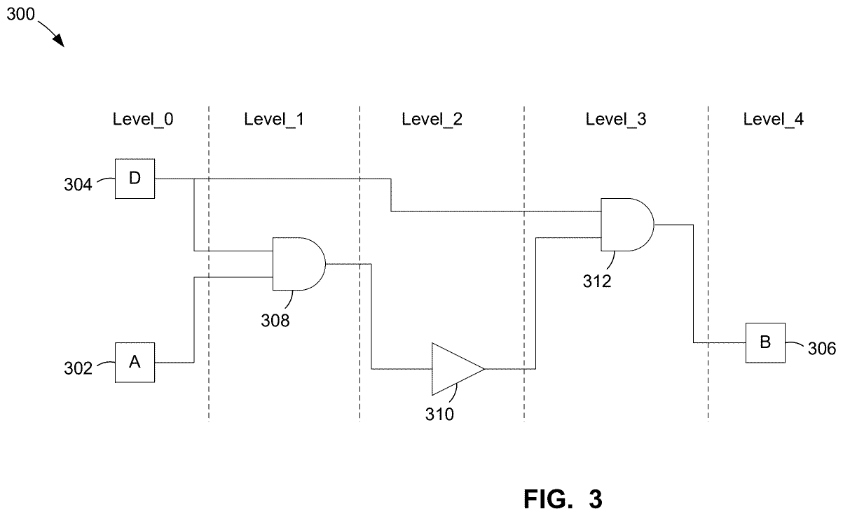

In FIG. 3, an exemplary netlist portion 300 includes two startpoints 302 (“A”) and 304 (“D”) and one endpoint 306 (“B”). The netlist portion 300 is shown in a levelized graph format, comprising the two startpoints 302 and 304 at Level_0, a cell 308 at Level_1, a cell 310 at Level_2, a cell 312 at Level 3, and the endpoint 306 at Level_4. The netlist portion 300 may represent a post-optimization configuration. As understood by one of ordinary skill in the art, the startpoints 302 and 304 and endpoint 306 may be sequential logic components, whereas the cells 308, 310 and 312 may be combinational logic components. In the example shown in FIG. 3, the above-described graph traversal engine 204 (FIG. 2) may be configured to determine the path having the worst (i.e., slowest) delay from all possible netlist startpoints to each netlist endpoint.

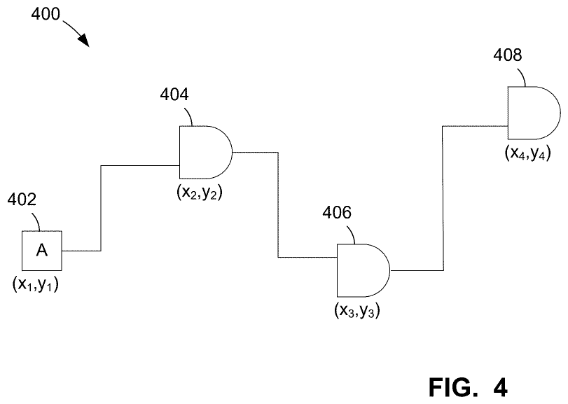

In FIG. 4, an exemplary netlist portion 400 may represent an unoptimized version of the above-described netlist portion 300 (FIG. 3) that includes placement information (i.e., x and y coordinates). Shown in the exemplary netlist portion 400 are: a startpoint 402 (“A”) at a location (x₁,y₁), corresponding to the startpoint 302 (FIG. 3) in the post-optimization netlist portion 300; a cell 404 at a location (x₂,y₂), corresponding to the cell 308 (FIG. 3) in the post-optimization netlist portion 300; a cell 406 at a location (x₃,y₃), corresponding to the cell 310 (FIG. 3) in the post-optimization netlist portion 300; and a cell 408 at a location (x₄,y₄), corresponding to the cell 312 (FIG. 3) in the post-optimization netlist portion 300. Using ML techniques, the above-described ML delay model 206 (FIG. 2) may predict the post-netlist optimization delays by learning the relationships between labels (delays) from the post-optimization netlist portion 300 plus placement information and features of the unoptimized netlist portion 400 plus placement information.

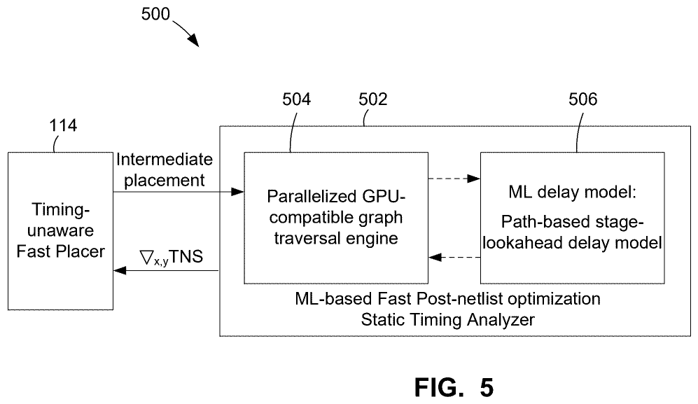

The solutions described herein include two alternative implementations or examples of the ML delay model 206 (FIG. 2). A first implementation or example is shown in the system 500 of FIG. 5, where such a ML delay model comprises a path-based stage-lookahead delay model 506. The remainder of the system 500 may be similar to the above-described system 200 (FIG. 2). That is, in a ML-based fast post-netlist optimization static timing analyzer 502, the path-based stage-lookahead delay model 506 may be coupled to a graph traversal engine 504. The graph traversal engine 504 may be similar to the above-described graph traversal engine 204 (FIG. 2).

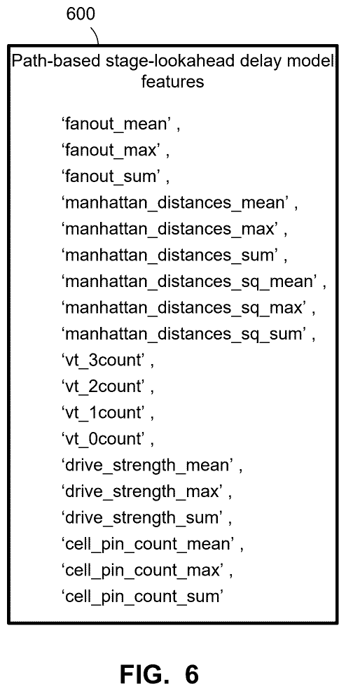

As shown in FIG. 6, a feature set 600 may be used to characterize features of cells and edges in the above-described path-based stage-lookahead delay model 506 (FIG. 5). The feature set 600 may include: a mean of the cell fanouts (‘fanout_mean’), a maximum of the cell fanouts (‘fanout_max’), a sum of the cell fanouts (‘fanout_sum’), a mean of the Manhattan distances between cells (‘manhattan_distance_mean’), a maximum of the Manhattan distances between cells (‘manhattan_distance_max’), a sum of the Manhattan distances between cells (‘manhattan_distance_sum’), a mean of the Manhattan distances squared (‘manhattan_distance_sq_mean’), a maximum of the Manhattan distances squared (‘manhattan_distance_sq_max’), a sum of the Manhattan distances squared (‘manhattan_distance_sq_sum’), a count of the number of cells having a first voltage threshold (‘vt_0count’), a count of the number of cells having a second voltage threshold (‘vt_1count’), a count of the number of cells having a third voltage threshold (‘vt_2count’), a count of the number of cells having a fourth voltage threshold (‘vt_3count’), a mean of the cell drive strengths (‘drive_strength_mean’), a maximum of the cell drive strengths (‘drive_strength_max’), a sum of the cell drive strengths (‘drive_strength_sum’), a mean of the cell pin counts (‘cell_pin_count_mean’), a maximum of the cell pin counts (‘cell_pin_count_max’), and a sum of the cell pin counts (‘cell_pin_count_sum’). Note that although in this example there are four voltage thresholds (VTs), in other examples there could be any other number. The cell drive strength, cell pin count, pin fanouts, edge Manhattan distance, and edge Manhattan distance squared may be aggregated across all cells along the path into mean, max and sum. Cell VTs are categorical variables, and the number of cells in each category along the path is considered as the feature. The aggregations are done because a ML model needs a fixed number of features (inputs), while the number of cells along a path can vary. Using a ML model having features defined by the feature set 600 may be less computationally intensive than the conventional method in which a timing-aware PnR tool may look up delays in a library or table that lists delays for all cell types that may be present in a netlist.

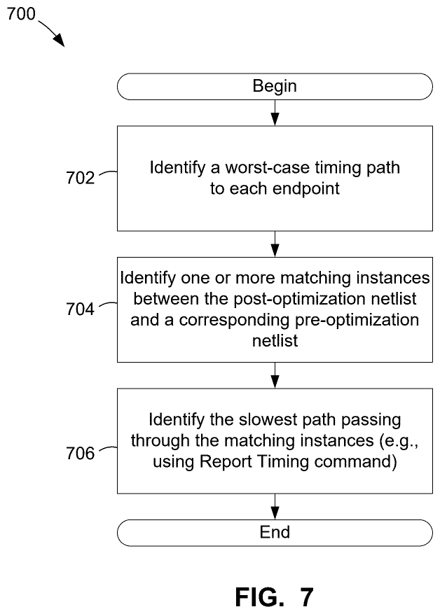

In FIG. 7, a method 700 for providing training samples for the above-described path-based stage-lookahead delay model 506 (FIG. 5) is shown in flow diagram form. A PnR tool may be used to manipulate netlist data, which may be obtained from, for example, databases available from previous chip designs. For example, such databases commonly include a netlist resulting from an initial coarse placement process performed by the PnR tool and a corresponding netlist resulting from a final placement process (i.e., post-optimization) performed by the PnR tool.

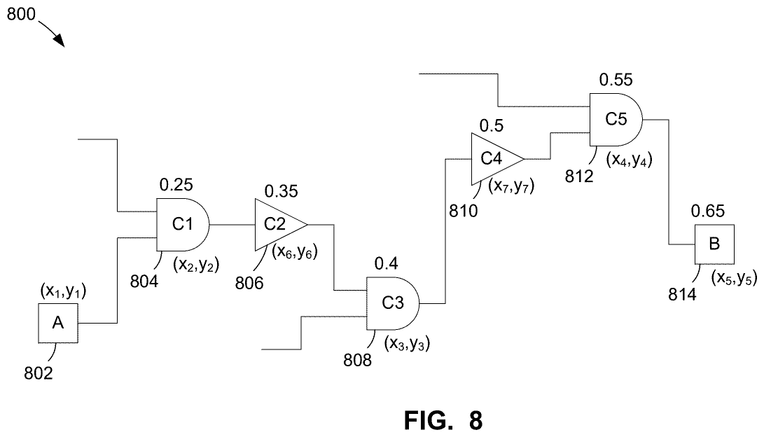

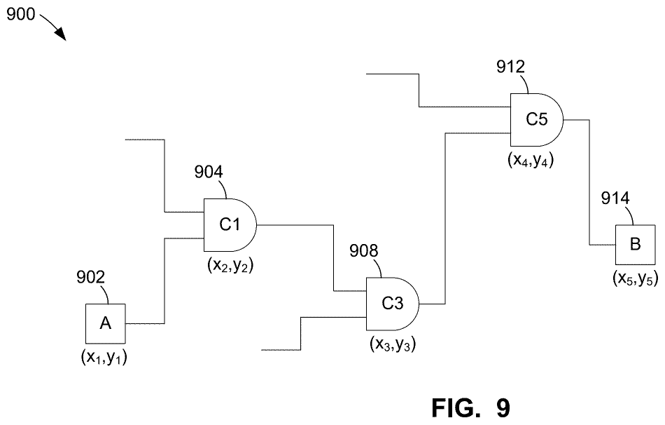

As indicated by block 702, the method 700 may include identifying the worst-case timing path to each endpoint in a post-optimization netlist. As indicated by block 704, the method 700 may also include identifying one or more matching instances between the post-optimization netlist and a corresponding pre-optimization or unoptimized netlist. That is, instances are identified in which cells match by name. (As in the example described below with regard to FIGS. 8-9, netlist cells are commonly assigned names, such as “C1,” “C2,” etc.) Accordingly, these matching instances would exclude, for example, cells added during optimization. As indicated by block 706, the method 700 may include identifying the slowest path passing through the matching instances in the same order. The slowest path may be identified using a command supported by the PnR tool that is commonly referred to as the Report Timing command.

In FIG. 8, an example of the operation of the above-referenced block 702 (FIG. 7) is shown. In FIG. 8, an exemplary netlist portion 800 represents a post-optimization state including placement information. The exemplary netlist portion 800 includes a startpoint 802 (“A”), a first cell 804 (“C1”), a second cell 806 (“C2”), a third cell 808 (“C3”), a fourth cell 810 (“C4”), a fifth cell 812 (“C5”), and an endpoint 814 (“B”). In the illustrated example: the arrival time to the first cell 804 (“C1”) may be 0.25; the arrival time to the second cell 806 (“C2”) may be 0.35; the arrival time to the third cell 808 (“C3”) may be 0.4; the arrival time to the fourth cell 810 (“C4”) may be 0.5; the arrival time to the fifth cell 812 (“C5”) may be 0.55; and the arrival time to the endpoint 814 (“B”) may be 0.65. These arrival times may be used as the labels for the above-described path-based stage-lookahead model 506 (FIG. 5). In the illustrated example, using the PnR tool it may be determined that the worst (i.e., slowest) path to the endpoint 814 (“B”) is the path beginning at the startpoint 802 (“A”) and passing through cells 804, 806, 808, 810 and 812.

In FIG. 9, an example of the operation of the above-referenced block 706 (FIG. 7) is shown. In FIG. 9, an exemplary netlist portion 900 represents a pre-optimization or unoptimized state corresponding to the above-described post-optimization netlist portion 800 (FIG. 8). The exemplary netlist portion 900 includes a startpoint 902 (“A”), a cell 904 (“C1”), a cell 908 (“C3”), a cell 912 (“C5”), and an endpoint 914 (“B”). Note that the cells named “C1,” “C3,” and “C5” match cells of the same name in the post-optimization netlist portion 800 (FIG. 8). That is, a matching path between the unoptimized netlist portion 900 and the post-optimization netlist portion 800 (FIG. 8) can be traced through cells 904 (“C1”), 908 (“C3”), and 912 (“C5”). Using the Report Timing command, the features of the cells 904 (“C1”), 908 (“C3”), and 912 (“C5”) may be extracted from the unoptimized netlist portion 900 (i.e., copied from the database or netlist files). The extracted features may be those described above with regard to the feature set 600 (FIG. 6). These features may then be used as training sample inputs to the path-based stage-lookahead delay model 506 (FIG. 5). The path-based stage-lookahead delay model 506 may be trained on these training samples in accordance with well-understood ML principles and, thus trained, the path-based stage-lookahead delay model 506 may operate in the manner described above.

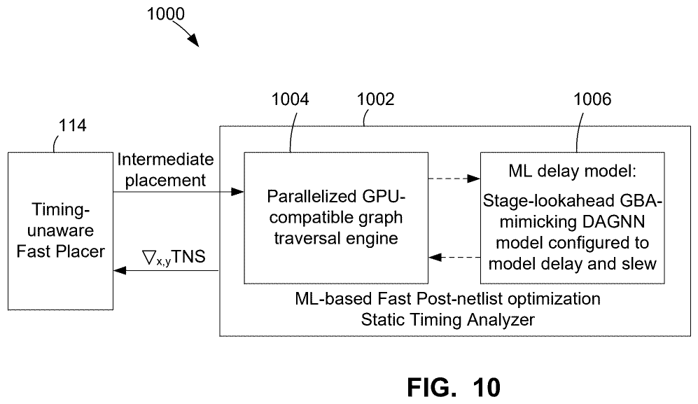

A second or alternative implementation or example is shown in the system 1000 of FIG. 10, where a ML delay model comprises a stage-lookahead graph-based analysis (GBA)-mimicking directed acyclic graph (DAG) neural network (DAGNN) model 1006 configured to model delay and slew. The remainder of the system 1000 may be similar to the above-described system 200 (FIG. 2). That is, in a ML-based fast post-netlist optimization static timing analyzer 1002, the stage-lookahead GBA-mimicking DAGNN model 1006 may be coupled to a graph traversal engine 1004. The graph traversal engine 1004 may be similar to the above-described graph traversal engine 204 (FIG. 2).

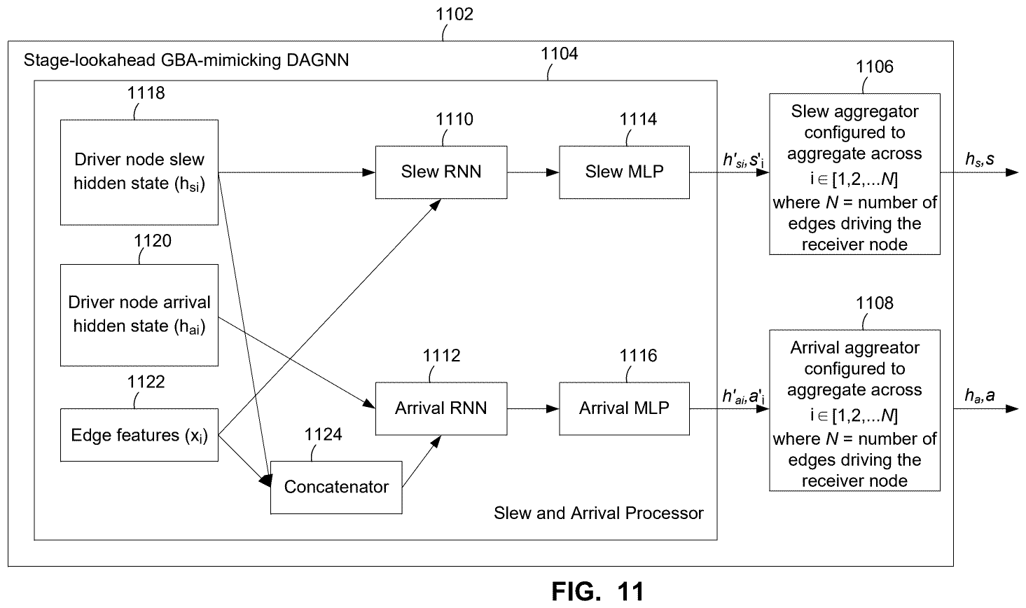

As shown in FIG. 11, a stage-lookahead GBA-mimicking DAGNN model 1102 may comprise a slew and arrival processor 1104, a slew aggregator 1106, and an arrival aggregator 1108. The stage-lookahead GBA-mimicking DAGNN model 1102 may be an example of the above-described stage-lookahead GBA-mimicking DAGNN model 1006 (FIG. 10). For brevity, the stage-lookahead GBA-mimicking DAGNN model 1102 may be referred to as the DAGNN model 1102.

The DAGNN model 1102 includes elements that, as described below, are together configured to model the passing of information from the i^{th} driver node to the receiver node (for a receiver node being driven by i edges). Nodes of a DAG may represent the data output pins of combinational or sequential cells, clock input pins of sequential cells, or data input pins of sequential cells. Edges of the DAG may be any of three types: (Type 1) combinational output pin or sequential data output pin directed to combinational data output pin (i.e., net delay+combinational cell delay); (Type 2) sequential clock input pin directed to sequential data output pin (i.e., clock-to-q sequential cell delay); and (Type 3) combinational or sequential output pin directed to sequential data input pin (i.e., net delay). Each node of the DAG has an arrival hidden state (vector), a slew hidden state (vector), an arrival (scalar), and a slew (scalar). The hidden states may be initialized to zero (vector zero) and updated using a topological message-passing sweep through the DAG. Each edge may be described by a set of edge features as follows.

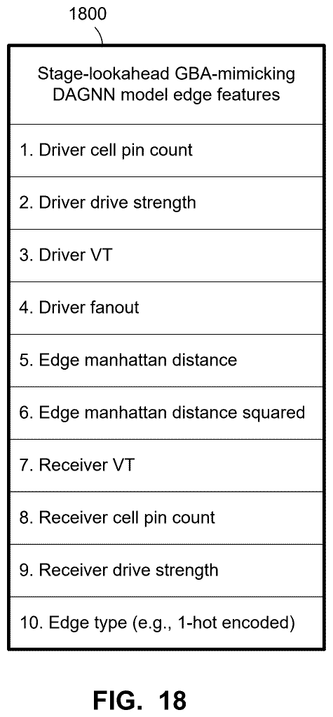

As shown in FIG. 18, a feature set 1800 may correspond to the edge features (vector) 1122 (xᵢ) that describes each edge in the DAGNN model 1102 (FIG. 11). The feature set 1800 may include: driver cell pin count, driver drive strength, driver voltage threshold (VT), driver fanout, edge Manhattan distance, edge Manhattan distance squared, receiver cell VT, receiver cell pin count, receiver drive strength, and edge type. The edge type may be encoded using, for example, one-hot encoding.

The DAGNN model 1102 processes information according to a flow defined by the partial order. As understood by one of ordinary skill in the art, in a DAG the edges define a partial ordering over the nodes. Each edge is directed from one node to another, never forming a combinational closed loop (only a sequential cell driving itself (a sequential loop) is allowed; a combinational cell cannot drive itself). Thus the combinational graph between sequentials is a DAG. In the DAGNN model 1102 the nodes may be processed according to the partial order, and the partial order may be used to provide inductive biases relating to signal arrival time and slew.

The slew and arrival processor 1104 may include a slew Recurrent Neural Network (RNN) 1110, an arrival RNN 1112, a slew Multi-Layer Perceptron (MLP) 1118, and an arrival MLP 1116. The slew and arrival processor 1104 may also include a driver node slew hidden state 1118 (hₛᵢ), a driver node arrival hidden state 1120 (hₐᵢ), and edge features 1122 (xᵢ). Other elements of the DAGNN model 1102 may include a concatenator 1124. The slew RNN 1110 may be configured to receive as inputs hidden state information from the driver node slew hidden state 1118 and edge feature information from the edge features 1122, and to provide as an output a receiver node candidate slew hidden state h′ₛᵢ. The slew MLP 1114 may be configured to convert the candidate slew hidden state h′ₛᵢ provided by the slew RNN 1110 to a candidate slew s′ᵢ (from a vector to a scalar (i.e., a real number)). Similarly, the arrival RNN 1112 may be configured to receive as inputs hidden state information from the driver node arrival hidden state 1120, driver node slew hidden state via the concatenator 1124, and edge feature information from the edge features 1122, and to provide as an output a receiver node candidate arrival hidden state h′ₐᵢ Note that via the concatenator 1124, the arrival RNN 1112 may receive hidden state information from the driver node slew hidden state 1118, which provides the DAGNN model 1102 with inductive bias to model the effect of input slew on cell delay. The arrival MLP 1116 may be configured to convert the candidate arrival hidden state h′ₐᵢ provided by the arrival RNN 1112 to a candidate arrival a′ᵢ (from a vector to a scalar). Stated another way, during each step of the graph traversal, the RNNs 1110 and 1112 aggregate edge features to create hidden states (vectors) representing the timing fan-in cone seen so far, while the MLPs 1114 and 1116 convert the respective hidden states (vectors) to arrival and slew (scalars). The foregoing operations, which determine slew and arrival for the i^{th} edge driving a receiver node, may be expressed in terms of equations:

$${{h}_{si}}^{′} = {RNN}_{s} ( {h}_{si} , {x}_{i} ) \qquad ( Eqn . 1 )$$

$${{s}^{′}}_{i} = {MLP}_{s} ( {{h}^{′}}_{si} ) \qquad ( Eqn . 2 )$$

$${{h}_{ai}}^{′} = {RNN}_{a} ( {h}_{ai} , [ {h}_{si} , {x}_{i} ] ) \qquad ( Eqn . 3 )$$

$$( note : [ {h}_{si} , {x}_{i} ] represents concatenation of vectors )$$

$${{a}^{′}}_{i} = {MLP}_{a} ( {{h}_{ai}}^{′} ) \qquad ( Eqn . 4 )$$

In the manner described above, N arrivals and N slews may be determined, where N is the number of edges driving the receiver node, and i ranges from 1 to N. (Note that when an edge is of the first of the three above-described types (i.e., Type 1), N equals the number of input pins of the receiver gate having timing areas to the receiver node (receiver combinational gate data output pin). For edges of Type 2 and Type 3, N equals 1, since there is only one clock driver for a sequential data output pin, and there is only one driver for a sequential data input pin. The slew aggregator 1106 aggregates across edges driving the receiver node and provides a receiver node slew(s). Similarly, the arrival aggregator 1108 aggregates across edges driving the receiver node and provides a receiver node arrival (a). After computing the worst arrival and worst slew, the hidden states corresponding to worst slew and worst arrival are assigned to the receiver node. These aggregation operations may be expressed in terms of equations:

$$a = max ( {a}_{1} {,}^{′} … , {{a}_{N}}^{′} ) \qquad ( Eqn . 5 )$$

$$s = max ( {s}_{1} {,}^{′} … , {{s}_{N}}^{′} ) \qquad ( Eqn . 6 )$$

$${h}_{a} = {{h}_{aj}}^{′} ; j = arg max ( {a}_{1} {,}^{′} … , {{a}_{N}}^{′} ) \qquad ( Eqn . 7 )$$

$${h}_{s} = {{h}_{sk}}^{′} ; k = arg max ( {s}_{1} {,}^{′} … , {{s}_{N}}^{′} ) \qquad ( Eqn . 8 )$$

It should be understood that in equations (1)-(4) above, the functions RNNₛ, MLPₛ, RNNₐ, and MLPₐ are not pre-known. That is, with reference to FIG. 11 the slew RNN 1110 and slew MLP 1114 learn their respective slew functions, while the arrival RNN 112 and arrival MLP 1116 learn their respective arrival functions from the training data. Also note that the worst slew and worst arrival are separately determined, because in some examples the worst arrival may come from a first edge while the worst slew may come from another edge driving the same receiver node. This aspect relates to mimicking graph-based analysis (GBA) and may also be referred to as “slew pessimism.”

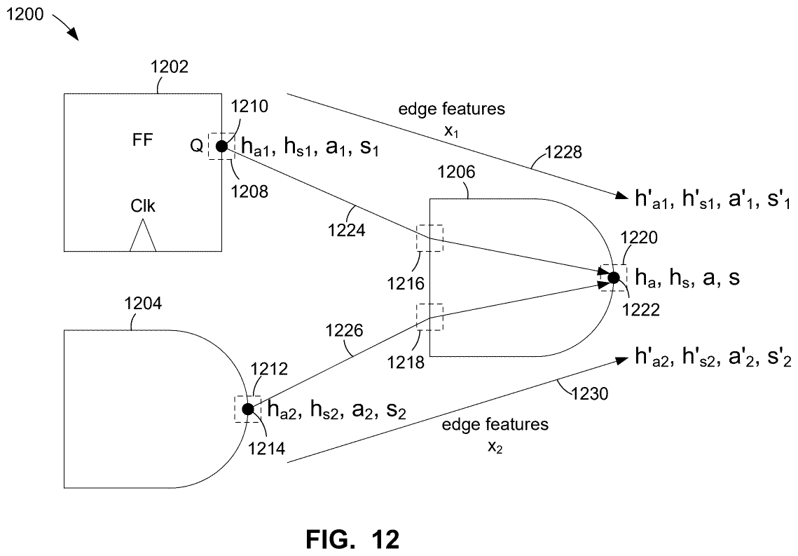

In FIG. 12, a modeled circuitry portion 1200 illustrates an example of operation of the above-described DAGNN model 1102 (FIG. 11). The modeled circuitry portion 1200 may include a first driver cell (e.g., a flip-flop) 1202, a second driver cell (e.g., an AND gate) 1204, and a receiver cell 1206 (e.g., a 2-input AND gate). The first driver cell 1202 may have a first driver cell output pin 1208, which may be modeled as a node 1210. The node 1210 may be described by a hidden state arrival vector hₐ₁, a hidden state slew vector hₛ₁, an arrival a₁, and a slew s₁. The second driver cell 1204 may have a second driver cell output pin 1212, which may be modeled as a node 1214. The node 1214 may be described by a hidden state arrival vector hₐ₂, a hidden state slew vector hₛ₂, an arrival a₂, and a slew s₂. The receiver cell 1206 may have a receiver cell first input pin 1216, a receiver cell second input pin 1218, and a receiver cell output pin 1220. The receiver cell output pin 1220 may be modeled as a node 1222. The node 1222 may be described by a hidden state arrival vector hₐ, a hidden state slew vector hₛ, an arrival a, and a slew s.

By operation of the DAGNN model 1102 (FIG. 11) on the circuitry portion 1200, the three nodes 1210, 1214 and 1222 participate in message passing. That is, message information may be passed from the node 1210 to the node 1222 along a first path 1224, which passes through the receiver cell first input pin 1216. Similarly, other message information may be passed from the node 1214 to the node 1222 along a second path 1226, which passes through the receiver cell second input pin 1218.

An edge 1228 directed from the node 1210 to the node 1222 may be described by an edge feature vector x₁. An edge 1230 directed from the node 1208 to the node 1222 may be described by an edge feature vector x₂. Note that the edge 1230 and the edge 1228 are both of the first type described above: from a combinational or sequential data output pin to a combinational data output pin. Accordingly, the delay and thus the arrival may be based on the net delay (i.e., delay of the signal through a trace of the interconnecting network) plus the delay of the receiver cell 1206.

Operation of the DAGNN model 1102 (FIG. 11) on the circuitry portion 1200 may provide two candidate vectors h′ₛ₁ and h′ₛ₂ for the slew hidden state of the node 1222 and two candidate vectors h′ₐ₁ and h′ₐ₂ for the arrival hidden state of the node 1222. Stated in equation form: h′ₛᵢ=RNN(hₛᵢ, xᵢ) and h′ₐᵢ=RNN(hₐᵢ, [hₛᵢ,xᵢ]), where i ranges from 1 to 2 (i.e., across all edges driving the receiver node 1222). Also provided are two candidates for the slew s′₁ and s′₂ scalar value of the node 1222 and two candidates for the arrival a′₁ and a′₂ scalar value of the node 1222. Stated in equation form: s′ᵢ=MLP(h′ₛᵢ) and a′ᵢ=MLP(h′ₐᵢ), where i ranges from 1 to 2. From the two candidate arrivals, one may be determined to be controlling, i.e., representing the worst-case arrival: a=max(a′₁, a′₂). Similarly, from the two candidate slews, one may be determined to be controlling, i.e., representing the worst-case slew: s=max(s′₁, s′₂). The new arrival hidden state of the node 1222 may be: hₐ=h′ₐⱼ, where j=argmax(a′₁, a′₂). Similarly, the new slew hidden state of the node 1222 may be: hₛ=h′ₛₖ, where k=argmax(s′₁, s′₂).

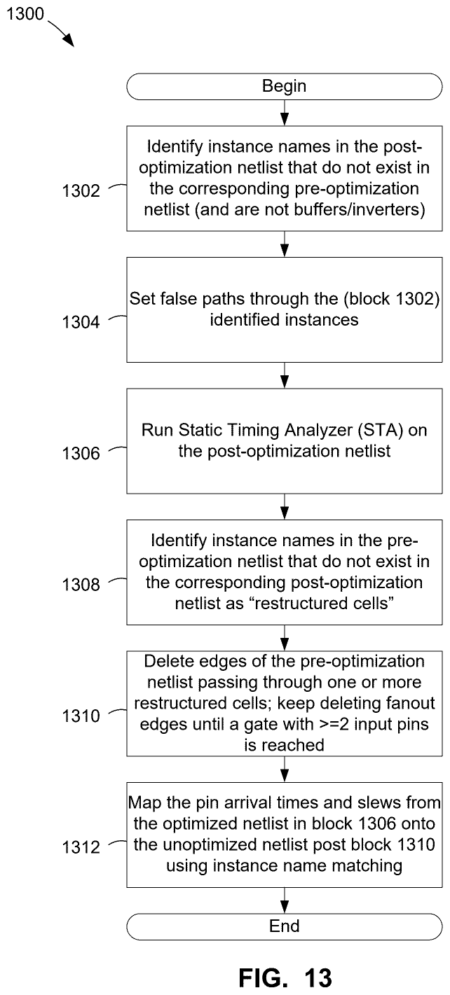

In FIG. 13, a method 1300 for providing training samples for the above-described DAGNN model 1102 (FIG. 11) is shown in flow diagram form. A PnR tool may be used to manipulate the netlist data, which may be obtained from, for example, databases available from previous chip designs. For example, such databases commonly include a netlist resulting from an initial coarse placement process performed by the PnR tool and a corresponding netlist resulting from a final placement process (i.e., post-optimization) performed by the PnR tool.

As indicated by block 1302, instance names in a post-optimization netlist that do not exist in the corresponding pre-optimization netlist and are not buffers or inverters may be identified. As indicated by block 1304, additional so-called “false paths” may be defined in the PnR tool through the instance names identified in block 1302. The command provided as input to the PnR tool may be in the form of, for example: set_false_path-through <instance names>. An example of blocks 1302-1304 is described below. As indicated by block 1306, STA may then be performed on the post-optimization netlist. The pin arrival times thus computed are the labels for the ML model. As indicated by block 1308, instances names in the pre-optimization netlist that do not exist in the corresponding post-optimization netlist as so-called “restructured cells” may be identified. As indicated by block 1310, unoptimized netlist edges passing through cells that become restructured in the corresponding optimized netlist may be deleted. Further deletions along the path following a deleted edge may be performed until a gate having more than one input pin (i.e., at least two input pins) is reached.

The pin arrival times computed in block 1306 may be mapped to the processed netlist in block 1310, to generate ML model training data. As noted above, an example of a feature set 1800 that may be used by a ML model such as the above-described DAGNN model 1102 (FIG. 11) is shown in FIG. 18. An example of block 1310 is described below.

The method 1300 may be used to generate training samples, and the DAGNN model 1102 (FIG. 11) may be trained on these training samples in accordance with well-understood ML principles. Thus trained on these training samples, the DAGNN model 1102 may operate in the manner described above.

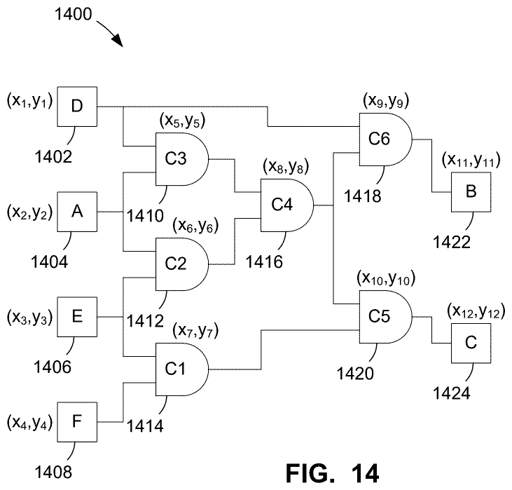

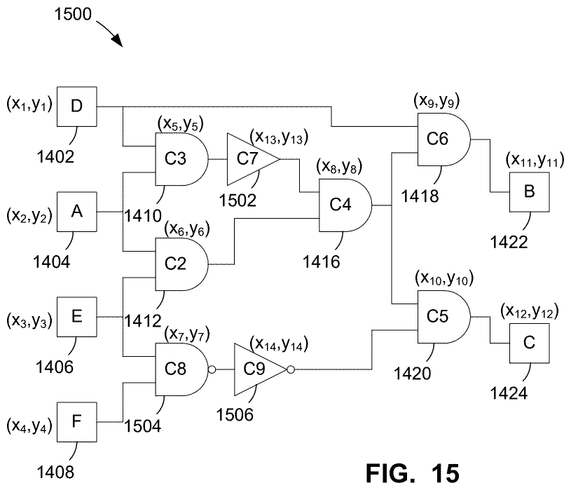

In FIGS. 14-15, an example of the operation of the above-referenced blocks 1302 and 1306 of the method 1300 (FIG. 13) are shown. In FIG. 14, an exemplary netlist portion 1400 represents an unoptimized or pre-optimization configuration. The exemplary netlist portion 1400 includes a first startpoint 1402 (“D”), a second startpoint 1404 (“A”), a third startpoint 1406 (“E”), and a fourth startpoint 1408 (“F”). The exemplary netlist portion 1400 also includes a first cell 1410 (“C3”), a second cell 1412 (“C2”), a third cell 1414 (“C1”), a fourth cell 1416 (“C4”), a fifth cell 1418 (“C6”), and a sixth cell 1420 (“C5”). The exemplary netlist portion 1400 further includes a first endpoint 1422 (“B”) and a second endpoint 1424 (“C”). It may be noted that in the illustrated example, all of the cells 1410-1420 are AND gates.

In FIG. 15, an exemplary netlist portion 1500 represents a post-optimization configuration. Note that the instance names in the netlist portion 1400 (FIG. 14) match the instance names in the corresponding netlist portion 1500 (FIG. 15) with the following exceptions: In the netlist portion 1500 (FIG. 15) optimization has resulted in an additional buffer cell 1502 (“C7”) being inserted between the output of the cell 1410 and the input of the cell 1416. That is, the buffer cell 1502 exists in the (post-optimization) netlist portion 1500 but does not exist in the corresponding (pre-optimization) netlist portion 1400. Also, cell 1504 (“C8”) and cell 1506 (“C9”) exist by those instance names (“C8” and “C9”) in the (post-optimization) netlist portion 1500 but do not exist by those instance names in the corresponding (pre-optimization) netlist portion 1400.

In accordance with block 1302 of the method 1300 (FIG. 13), commands may be provided to the PnR tool to set false paths through cell 1504 (“C8”). Stated another way, block 1302 indicates that where the optimization process results in netlist restructuring, the PnR tool may be instructed to set false paths through the restructured paths.

In accordance with block 1306 of the method 1300 (FIG. 13), unoptimized netlist edges passing through cell 1414 (“C1”) may be deleted. Note that the optimization in the illustrated example restructures cell 1414 (“C1”) in the (unoptimized) netlist portion 1400 into the combination of cells 1504 (“C8”) and 1506 (“C9”) in the (post-optimization) netlist portion 1500 (FIG. 15). Cell 1414 (“C1”), which is a 2-input AND gate in the (unoptimized) netlist portion 1400 (FIG. 14), becomes (post-optimization) a 2-input NAND gate, i.e., cell 1504 (“C8”) plus an inverter, i.e., cell 1506 (“C9”). The edges corresponding to the two inputs of cell 1414 (“C1”) and the edge corresponding to the output of cell 1414 may be deleted using the PnR tool. In this signal path, the output of cell 1414 is coupled to the input of cell 1420 (a 2-input AND gate). As the condition in block 1306 is that further edge deletions that may be made along the signal path may cease upon reaching a cell having more than one input pin, no further edge deletions need be performed upon reaching the cell 1420.

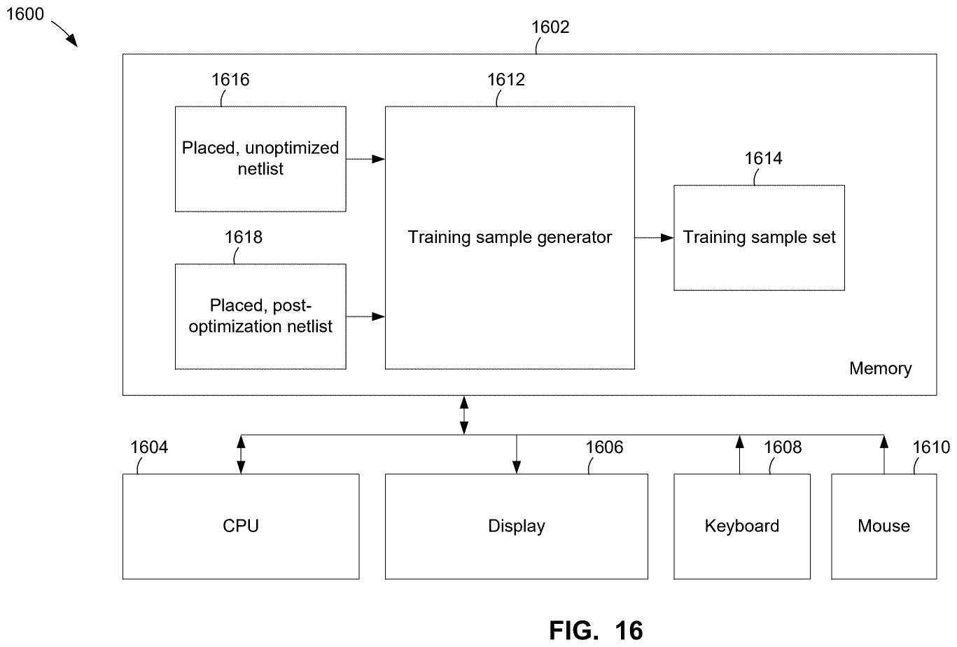

In FIG. 16, a computing system 1600 may include hardware components such as a memory 1602, a CPU 1604, a display 1606, a keyboard 1608, a mouse 1610, etc. In a manner similar to that described above with regard to the computing system 100 (FIG. 1), the computing system 1600 may also include software components, such as a training sample generator 1612. The training sample generator 1612 may configure the processing system comprising the memory 1602 and CPU 1604 to perform the above-described method 700 (FIG. 7) for generating a training sample set 1614 for use in training the above-described path-based stage-lookahead delay model 506 (FIG. 5). Alternatively, or in addition, the training sample generator 1612 may configure the processing system comprising the memory 1602 and CPU 1604 to perform the above-described method 1300 (FIG. 13) for generating the training sample set 1614 for use in training the above-described DAGNN model 1102 (FIG. 11). The training sample generator 1612 may generate or provide the training sample set 1614 based on a placed unoptimized netlist 1616 and a corresponding placed post-optimization netlist 1618, as described above with regard to the method 700 or the method 1300.

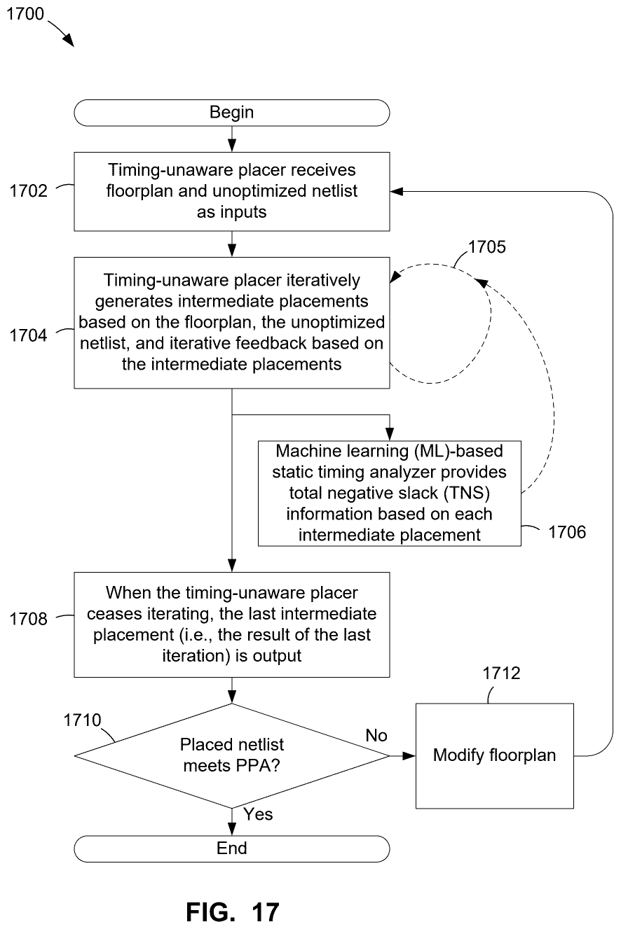

In FIG. 17, a method 1700 may illustrate an example of operation of the above-described timing-aware fast placer 112 (FIG. 1). As understood by one of ordinary skill in the art, such operation may be controlled by a user, such as a user of the computing system 100 (FIG. 1). As indicated by block 1702, a timing-unaware fast placer may receive a floorplan and an unoptimized netlist as inputs. As indicated by block 1704, the timing-unaware fast placer may iteratively generate intermediate placements based on the floorplan, the unoptimized netlist, and iterative feedback 1705. The iterative feedback 1705 may be based on the intermediate placements. For example, the timing-unaware fast placer may internally generate a portion of the iterative feedback 1705, e.g., using a cost function included in (i.e., internal to) the timing-unaware fast placer.

As indicated by block 1706, an additional portion of the iterative feedback 1705 may be provided by a ML-based static timing analyzer. This additional portion of the iterative feedback 1705 may comprise total negative slack (TNS) gradient information based on each intermediate placement. That is, on each iteration the ML-based static timing analyzer may analyze the intermediate placement that the timing-unaware fast placer provides on that iteration, determine a TNS gradient value for that intermediate placement, and include that TNS gradient value in the iterative feedback 1705 provided to the timing-unaware fast placer.

The timing-unaware fast placer may use the portion of the feedback 1705 that is internally determined (e.g., by a cost function) in combination with the TNS gradient information portion of the feedback 1705 to provide another intermediate placement on the next iteration. Any number of iterations (e.g., tens, hundreds, etc.) may be performed in this manner. As indicated by block 1708, when the timing-unaware fast placer ceases iterating, it may output the intermediate placement that it provided on the last iteration. The timing-unaware fast placer may determine when to cease iterating by, for example, comparing the TNS gradient information or other metrics describing the intermediate placement with threshold values and iterate until the threshold values are reached.

As indicated by block 1710, the resulting placement of the netlist may then be evaluated for PPA using ML models (e.g., the feature 118′ of the ML-based fast post-netlist-optimization Static Timing Analyzer 118 described above with regard to FIG. 1). As described above, this feature 118′ may provide endpoint arrival times. If the placed netlist does not meet PPA requirements, then the floorplan may be modified (e.g., by a user), as indicated by block 1712. The method 1700 may then be repeated using the modified floorplan.

In the above-described manner, a user may quickly determine whether a floorplan is conducive to a satisfactory placement. Based on the fast placement results, the user may choose to similarly evaluate a different floorplan. In this manner, the user may quickly evaluate multiple floorplans in a “floorplan exploration” sub-phase before settling on a floorplan and using a full-featured PnR tool to complete the placement. Speeding the floorplanning exploration sub-phase may reduce the amount of time devoted to the overall floorplanning and placement phases of the chip design process.

Implementation examples are described in the following numbered clauses:

1. A method for providing a placement in designing an integrated circuit chip, comprising:
receiving, by a placer, a floorplan and an unoptimized netlist, the placer configured to iteratively generate and evaluate intermediate placements based on the floorplan, the unoptimized netlist, and iterative feedback based on the intermediate placements;
providing, by a machine learning (ML)-based static timing analyzer, total negative slack (TNS) gradient information based on the intermediate placements; and
providing, by the placer, an output placement comprising a last iteration of the intermediate placements, wherein the iterative feedback includes the TNS gradient information.

2. The method of clause 1, wherein providing the TNS gradient information comprises determining a slowest delay from all possible startpoints in the netlist to each endpoint in the netlist using a ML-based delay predictor.

3. The method of clause 2, wherein the ML-based delay predictor comprises a path-based stage-lookahead delay model.

4. The method of clause 3, wherein the path-based stage-lookahead delay model comprises a set of cell features including: cell voltage, cell drive strength, cell pin count, pin fanout, and edge Manhattan distance.

5. The method of clause 3 or 4, further comprising providing a plurality of training samples for the path-based stage-lookahead delay model including:
identifying a worst-case timing path to each endpoint in a post-optimization netlist;
identifying one or more matching instances between the post-optimization netlist and a corresponding pre-optimization netlist; and
identifying a slowest path passing through the matching instances.

6. The method of clause 2, wherein the ML-based delay predictor comprises a stage-lookahead directed acyclic graph neural network (DAGNN) configured to model delay and slew.

7. The method of clause 6, further comprising providing a plurality of training samples for the DAGNN including:
defining one or more false paths having instance names in a post-optimization netlist not existing in a corresponding pre-optimization netlist for cells that are not buffers or inverters;
mapping, for each pin in the post-optimization netlist, a slowest arrival time onto the pre-optimization netlist; and
deleting edges of the pre-optimization netlist passing through one or more restructured cells.

8. A computer-readable medium storing computer-executable code, comprising:
a placer configured to receive a floorplan and an unoptimized netlist and to iteratively generate and evaluate intermediate placements based on the floorplan, the unoptimized netlist, and iterative feedback based on the intermediate placements; and
a machine learning (ML)-based static timing analyzer configured to provide total negative slack (TNS) gradient information based on the intermediate placements, wherein the placer is further configured to provide an output placement comprising a last iteration of the intermediate placements, wherein the iterative feedback includes the TNS gradient information.

9. The computer-readable medium of clause 8, wherein providing the TNS gradient descent-driven feedback comprises determining a slowest delay in the netlist to each endpoint in the netlist using a ML-based delay predictor.

10. The computer-readable medium of clause 9, wherein the ML-based delay predictor comprises a path-based stage-lookahead delay model.

11. The computer-readable medium of clause 10, wherein the path-based stage-lookahead delay model comprises a set of cell features including: cell voltage, cell drive strength, cell pin count, pin fanout, and edge Manhattan distance.

12. The computer-readable medium of clause 10 or 11, further comprising a training sample generator configured to provide a plurality of training samples for the path-based stage-lookahead delay model, the training sample generator configured to:
identify a worst-case timing path to each endpoint in a post-optimization netlist;
identify one or more matching instances between the post-optimization netlist and a corresponding pre-optimization netlist; and
identify a slowest path passing through the matching instances.

13. The computer-readable medium of clause 9, wherein the ML-based delay predictor comprises a stage-lookahead directed acyclic graph neural network (DAGNN) configured to model delay and slew.

14. The computer-readable medium of clause 13, further comprising a training sample generator configured to provide a plurality of training samples for the DAGNN, the training sample generator configured to:
define one or more false paths having instance names in a post-optimization netlist not existing in a corresponding pre-optimization netlist for cells that are not buffers or inverters;
map, for each pin in the post-optimization netlist, a slowest arrival time onto the pre-optimization netlist; and
delete edges of the pre-optimization netlist passing through one or more restructured cells.

15. A system for providing a placement in designing an integrated circuit chip, comprising:
a user interface; and
a processing system comprising one or more memories and one or more processors, the processing system configured to include:
a placer configured to receive a floorplan and an unoptimized netlist and to iteratively generate and evaluate intermediate placements based on the floorplan, the unoptimized netlist, and iterative feedback based on the intermediate placements; and
a machine learning (ML)-based static timing analyzer configured to provide total negative slack (TNS) gradient information based on the intermediate placements, wherein the placer is further configured to provide an output placement comprising a last iteration of the intermediate placements, wherein the iterative feedback includes the TNS gradient information.

16. The system of clause 15, wherein providing the TNS gradient descent-driven feedback comprises determining a slowest delay in the netlist to each endpoint in the netlist using a ML-based delay predictor.

17. The system of clause 16, wherein the ML-based delay predictor comprises a path-based stage-lookahead delay model.

18. The system of clause 17, wherein the path-based stage-lookahead delay model comprises a set of cell features including: cell voltage, cell drive strength, cell pin count, pin fanout, and edge Manhattan distance.

19. The system of clause 17 or 18, further comprising a training sample
generator configured to provide a plurality of training samples for the path-based stage-lookahead delay model, the training sample generator configured to:
identify a worst-case timing path to each endpoint in a post-optimization netlist;
identify one or more matching instances between the post-optimization netlist and a corresponding pre-optimization netlist; and
identify a slowest path passing through the matching instances.

20. The system of clause 16, wherein the ML-based delay predictor comprises a stage-lookahead directed acyclic graph neural network (DAGNN) configured to model delay and slew.

Alternative embodiments will become apparent to one of ordinary skill in the art to which the invention pertains. Therefore, although selected aspects have been illustrated and described in detail, it will be understood that various substitutions and alterations may be made therein.

What is claimed is:

1. A method for providing a placement in designing an integrated circuit chip, comprising:
receiving, by a placer, a floorplan and a netlist, the placer configured to iteratively generate and evaluate intermediate placements based on the floorplan, the netlist, and iterative feedback based on the intermediate placements;
providing, by a machine learning (ML)-based static timing analyzer, total negative slack (TNS) gradient information based on the intermediate placements; and
providing, by the placer, an output placement comprising a last iteration of the intermediate placements, wherein the iterative feedback includes the TNS gradient information.

2. The method of claim 1, wherein providing the TNS gradient information comprises determining a slowest delay from all possible startpoints in the netlist to each endpoint in the netlist using a ML-based delay predictor.

3. The method of claim 2, wherein the ML-based delay predictor comprises a path-based stage-lookahead delay model.

4. The method of claim 3, wherein the path-based stage-lookahead delay model comprises a set of cell features including: cell voltage, cell drive strength, cell pin count, pin fanout, and edge Manhattan distance.

5. The method of claim 3, further comprising providing a plurality of training samples for the path-based stage-lookahead delay model, including:
identifying a worst-case timing path to each endpoint in a post-optimization netlist;
identifying one or more matching instances between the post-optimization netlist and a corresponding pre-optimization netlist; and
identifying a slowest path passing through the matching instances.

6. The method of claim 2, wherein the ML-based delay predictor comprises a stage-lookahead directed acyclic graph neural network (DAGNN) configured to model delay and slew.

7. The method of claim 6, further comprising providing a plurality of training samples for the DAGNN, including:
defining one or more false paths having instance names in a post-optimization netlist not existing in a corresponding pre-optimization netlist for cells that are not buffers or inverters;
mapping, for each pin in the post-optimization netlist, a slowest arrival time onto the pre-optimization netlist; and
deleting edges of the pre-optimization netlist passing through one or more restructured cells.

8. A computer-readable medium storing computer-executable code, comprising:
a placer configured to receive a floorplan and a netlist and to iteratively generate and evaluate intermediate placements based on the floorplan, the netlist, and iterative feedback based on the intermediate placements; and
a machine learning (ML)-based static timing analyzer configured to provide total negative slack (TNS) gradient information based on the intermediate placements, wherein the placer is further configured to provide an output placement comprising a last iteration of the intermediate placements, wherein the iterative feedback includes the TNS gradient information.

9. The computer-readable medium of claim 8, wherein providing the TNS gradient descent-driven feedback comprises determining a slowest delay in the netlist to each endpoint in the netlist using a ML-based delay predictor.

10. The computer-readable medium of claim 9, wherein the ML-based delay predictor comprises a path-based stage-lookahead delay model.

11. The computer-readable medium of claim 10, wherein the path-based stage-lookahead delay model comprises a set of cell features including: cell voltage, cell drive strength, cell pin count, pin fanout, and edge Manhattan distance.

12. The computer-readable medium of claim 10, further comprising a training sample generator configured to provide a plurality of training samples for the path-based stage-lookahead delay model, the training sample generator configured to:
identify a worst-case timing path to each endpoint in a post-optimization netlist;
identify one or more matching instances between the post-optimization netlist and a corresponding pre-optimization netlist; and
identify a slowest path passing through the matching instances.

13. The computer-readable medium of claim 9, wherein the ML-based delay predictor comprises a stage-lookahead directed acyclic graph neural network (DAGNN) configured to model delay and slew.

14. The computer-readable medium of claim 13, further comprising a training sample generator configured to provide a plurality of training samples for the DAGNN, the training sample generator configured to:
define one or more false paths having instance names in a post-optimization netlist not existing in a corresponding pre-optimization netlist for cells that are not buffers or inverters;
map, for each pin in the post-optimization netlist, a slowest arrival time onto the pre-optimization netlist; and
delete edges of the pre-optimization netlist passing through one or more restructured cells.

15. A system for providing a placement in designing an integrated circuit chip, comprising:
a user interface; and
a processing system comprising one or more memories and one or more processors, the processing system configured to include:
a placer configured to receive a floorplan and a netlist and to iteratively generate and evaluate intermediate placements based on the floorplan, the netlist, and iterative feedback based on the intermediate placements; and
a machine learning (ML)-based static timing analyzer configured to provide total negative slack (TNS) gradient information based on the intermediate placements, wherein the placer is further configured to provide an output placement comprising a last iteration of the intermediate placements, wherein the iterative feedback includes the TNS gradient information.

16. The system of claim 15, wherein providing the TNS gradient descent-driven feedback comprises determining a slowest delay in the netlist to each endpoint in the netlist using a ML-based delay predictor.

17. The system of claim 16, wherein the ML-based delay predictor comprises a path-based stage-lookahead delay model.

18. The system of claim 17, wherein the path-based stage-lookahead delay model comprises a set of cell features including: cell voltage, cell drive strength, cell pin count, pin fanout, and edge Manhattan distance.

19. The system of claim 17, further comprising a training sample generator configured to provide a plurality of training samples for the path-based stage-lookahead delay model, the training sample generator configured to:
identify a worst-case timing path to each endpoint in a post-optimization netlist;
identify one or more matching instances between the post-optimization netlist and a corresponding pre-optimization netlist; and
identify a slowest path passing through the matching instances.

20. The system of claim 16, wherein the ML-based delay predictor comprises a stage-lookahead directed acyclic graph neural network (DAGNN) configured to model delay and slew.
